(19) United States
(12) Patent Application Publication
(10) Pub. No.: US 2017/0050842 A1
(43) Pub. Date: Feb. 23, 2017

(54) PRINTED WIRING BOARD AND MAGNETICSHIELD PACKAGE

(71) Applicant: KABUSHIKI KAISHA TOSHIBA, Tokyo (JP)

(72) Inventors: Keiju YAMADA, Yokohama Kanagawa (JP); Kazuo SHIMOKAWA, Yokohama Kanagawa (JP); Tomohiro IGUCHI, Kawasaki Kanagawa (JP); Michiko HARA, Yokohama Kanagawa (JP); Motomichi SHIBANO, Atsugi Kanagawa (JP)

(73) Assignee: KABUSHIKI KAISHA TOSHIBA, Tokyo (JP)

(21) Appl. No.: 15/242,373

(22) Filed: Aug. 19, 2016

(30) Foreign Application Priority Data
Aug. 21, 2015 (JP) 2015-164251

(51) Int. Cl. B81B 7/00; H01L 23/522; H01L 23/552; H01L 23/498

(52) U.S. Cl. CPC B81B 7/0064; H01L 23/49838; H01L 23/5225; H01L 23/552; H01L 27/222

(57) ABSTRACT

According to one embodiment, a printed wiring board includes a first magnetic layer, a second magnetic layer, an insulating layer, a first conductor layer, and a second conductor layer. The insulating layer is provided between the first magnetic layer and the second magnetic layer. The first conductor layer is provided between the insulating layer and the first magnetic layer. The second conductor layer is provided between the insulating layer and the second magnetic layer.

### CROSS-REFERENCE TO RELATED APPLICATIONS

This application is based upon and claims the benefit of priority from Japanese Patent Application No. 2015-164251, filed on Aug. 21, 2015; the entire contents of which are incorporated herein by reference.

### FIELD

Embodiments described herein relate generally to a printed wiring board and a magnetic shield package.

### BACKGROUND

Increase of a frequency of a clock in a stored circuit and a data transmission rate in a wireless communication device causes a high frequency noise due to the increase. The high frequency noise may decrease receiver sensitivity of the wireless communication device and make the communication difficult.

### BRIEF DESCRIPTION OF THE DRAWINGS

FIG. 1A and FIG. 1B are schematic cross-sectional views illustrating a printed wiring board according to a first embodiment;

FIG. 2A to FIG. 2D are schematic cross-sectional views illustrating a method for manufacturing the printed wiring board according to the first embodiment;

FIG. 3A to FIG. 3C are schematic cross-sectional views illustrating the method for manufacturing the printed wiring board according to the first embodiment;

FIG. 4A and FIG. 4B show graphs illustrating characteristics of the printed wiring board;

FIG. 5 is a schematic cross-sectional view of another example of the printed wiring board according to the first embodiment;

FIG. 6A to FIG. 6D are schematic cross-sectional views illustrating a method for manufacturing another example of the printed wiring board according to the first embodiment;

FIG. 7A to FIG. 7C are schematic cross-sectional views illustrating the method for manufacturing another example of the printed wiring board according to the first embodiment;

FIG. 8A and FIG. 8B are schematic cross-sectional views illustrating a magnetic shield package according to a second embodiment;

FIG. 9 shows a graph illustrating characteristics of the magnetic shield package;

FIG. 10 is a schematic cross-sectional view of another example of the magnetic shield package according to the second embodiment; and

FIG. 11A and FIG. 11B are schematic cross-sectional views illustrating a magnetic shield package according to a third embodiment.

### DETAILED DESCRIPTION

According to one embodiment, a printed wiring board includes a first magnetic layer, a second magnetic layer, an insulating layer, a first conductor layer, and a second conductor layer. The insulating layer is provided between the first magnetic layer and the second magnetic layer. The first conductor layer is provided between the insulating layer and the first magnetic layer. The second conductor layer is provided between the insulating layer and the second magnetic layer.

According to another embodiment, a magnetic shield package includes a printed wiring board and a first shield section. The printed wiring board includes a first magnetic layer, a second magnetic layer, an insulating layer, a first conductor layer, and a second conductor layer. The insulating layer is provided between the first magnetic layer and the second magnetic layer. The first conductor layer is provided between the insulating layer and the first magnetic layer. The second conductor layer is provided between the insulating layer and the second magnetic layer. The first shield section includes a first portion, a second portion, and a third portion. The first portion is along a first direction from the second magnetic layer toward the first magnetic layer. The second portion is arranged with the first portion in a second direction and along the first direction. The second direction intersects the first direction. The third portion is along the second direction. The first magnetic layer, the second magnetic layer, the first conductor layer and the second conductor layer are provided between the first portion and the second portion. The third portion overlaps the first magnetic layer in the first direction.

Various embodiments will be described hereinafter with reference to the accompanying drawings.

In the specification and drawings, components similar to those described or illustrated in a drawing thereinabove are marked with like reference numerals, and a detailed description is omitted as appropriate.

### First Embodiment

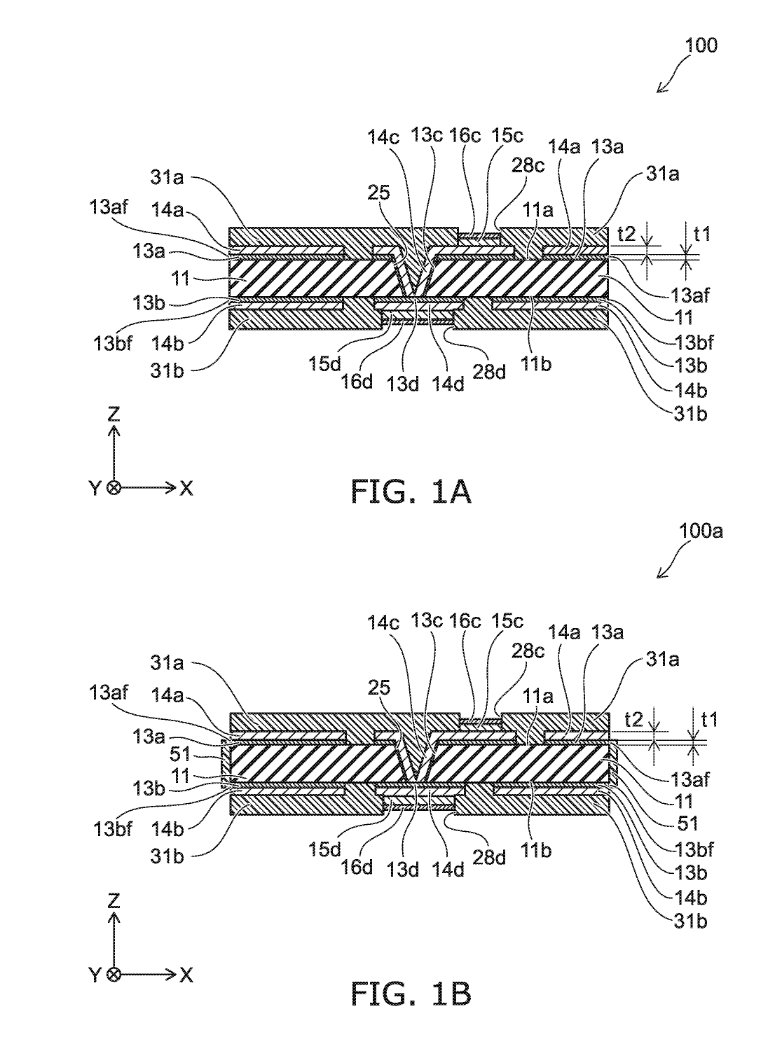

FIG. 1A and FIG. 1B are schematic cross-sectional views illustrating a printed wiring board according to a first embodiment.

As show in FIG. 1A, a first magnetic layer 14a and a second magnetic layer 14b are provided in a printed wiring board 100 according to a first embodiment. An insulating layer 11 is provided between the first magnetic layer 14a and the second magnetic layer 14b. A first conductor layer 13a is provided between the insulating layer 11 and the first magnetic layer 14a. A second conductor layer 13b is provided between the insulating layer 11 and the second magnetic layer 14b. The insulating layer 11 has an upper surface 11a (first surface) and a lower surface 11b (second surface) opposite the upper surface 11a. The first magnetic layer 14a and the first conductor layer 13a are provided on the upper surface 11a. The second magnetic layer 14b and the second conductor layer 13b are provided on the lower surface 11b.

A direction intersecting a contact plane of the insulating layer 11 and the first conductor layer 13a is taken as a “first direction”. A direction intersecting the first direction is taken as a “second direction”. A direction intersecting the first direction and the second direction is taken as a “third direction”.

The “first direction” is taken as a “Z-direction”. One direction orthogonal to the Z-direction is taken as an “X-direction”. A direction orthogonal to the Z-direction and the X-direction is taken as a “Y-direction”.

For example, the first magnetic layer 14a is not provided on a side surface 13af of the first conductor layer 13a intersecting a direction perpendicular to the Z-direction. For example, the second magnetic layer 14b is not provided on a side surface 13bf of the second conductor layer 13b intersecting a direction perpendicular to the Z-direction. That is, the first magnetic layer 14a is not connected to the first conductor layer 13a in the X-direction. The second magnetic layer 14b is not connected to the second conductor layer 13b in the X-direction.

A via 25 piercing the insulating layer 11 in the Z-direction is provided. A magnetic layer 14c (third magnetic layer) is provided on the insulating layer 11. A magnetic layer 14d (fourth magnetic layer) is provided below the insulating layer 11. A conductor layer 13c (first wiring layer) is provided between the insulating layer 11 and the magnetic layer 14c. A conductor layer 13d (second wiring layer) is provided between the insulating layer 11 and the magnetic layer 14d. The conductor layer 13c is provided on the upper surface 11a and is apart from the first magnetic layer 14a and the first conductor layer 13a. In other words, the conductor layer 13c is electrically insulated from the first magnetic layer 14a and the first conductor layer 13a. The conductor layer 13d is provided on the lower surface 11b and is apart from the second magnetic layer 14b and the second conductor layer 13b. In other words, the conductor layer 13d is electrically insulated from the second magnetic layer 14b and the second conductor layer 13b. The conductor layer 13d is electrically connected to the conductor layer 13c through the via 25. The magnetic layer 14c and the magnetic layer 14d are electrically connected via the conductor layer 13c and the conductor layer 13d.

An electrode layer 16c and an electrode layer 16d are further provided in the printed wiring board 100. An electrode layer 15c is provided between the magnetic layer 14c and the electrode layer 16c. An electrode layer 15d is provided between the magnetic layer 14d and the electrode layer 16d. The electrode layer 16c and the electrode layer 16d are electrically connected.

The electrode layer 16c is, for example, connected to a signal line. The electrode layer 16c may be, for example, connected to a ground. A ground potential is applied to the ground.

A solder resist film 31a is provided on the insulating layer 11. The solder resist film 31a is further provided on the first magnetic layer 14a. The solder resist film 31a is further provided in the via 25. A resist film 31b is provided below the insulating layer 11. The resist film 31b is further provided below the second magnetic layer 14b. The solder resist film 31a is not provided on the electrode layer 16c. The resist film 31b is not provided below the electrode layer 16d.

The insulating layer 11 includes, for example, at least one of a glass epoxy, a fluororesin, and a ceramic.

At least one of the first conductor layer 13a, the second conductor layer 13b, the conductor layer 13c and the conductor layer 13d includes a conductor Q of a non-magnetic body. A relative permeability of the conductor Q of the non-magnetic body is, for example, not less than 1.0 and not more than 2.0. The relative permeability of the conductor Q of the non-magnetic body is generally the same as a relative permeability of vacuum. A resistivity of the conductor Q of the non-magnetic body is, for example, not less than 1.5×10⁻⁸ Ω·m (ohm meter) and not more than 1.0×10⁻⁶ Ω·m.

At least one of the first conductor layer 13a, the second conductor layer 13b, the conductor layer 13c and the conductor layer 13d includes, for example, at least one of copper (Cu), gold (Au), silver (Ag) and aluminum (Al).

At least one of the first conductor layer 13a, the second conductor layer 13b, the conductor layer 13c and the conductor layer 13d includes, for example, at least one of an elemental substance of a metal with a high conductivity and an alloy of the metal. At least one of the first conductor layer 13a, the second conductor layer 13b, the conductor layer 13c and the conductor layer 13d may include, for example, a paste material including the elemental substance of the metal with a high conductivity and a resin. At least one of the first conductor layer 13a, the second conductor layer 13b, the conductor layer 13c and the conductor layer 13d may include, for example, a paste material including the alloy of the metal with a high conductivity and the resin. At least one of the first conductor layer 13a, the second conductor layer 13b, the conductor layer 13c and the conductor layer 13d may include, for example, a paste material including the elemental substance of the metal with a high conductivity, the alloy of the metal and the resin.

At least one of the first magnetic layer 14a, the second magnetic layer 14b, the magnetic layer 14c and the magnetic layer 14d includes a conductor M of a soft magnetic body. A coercive force of the conductor M of the soft magnetic body is, for example, less than 5000 A/m (ampere per meter). A relative permeability of the conductor M of the soft magnetic body is, for example, not less than 100.

A resistivity of the conductor M of the soft magnetic body is, for example, not less than 5×10⁻⁸ Ω·m and not more than 1.0×10⁻⁴ Ω·m.

At least one of the first magnetic layer 14a, the second magnetic layer 14b, the magnetic layer 14c and the magnetic layer 14d includes, for example, at least one of iron (Fe), nickel (Ni) and cobalt (Co). The first magnetic layer 14a, the second magnetic layer 14b, the magnetic layer 14c and the magnetic layer 14d include, for example, a soft magnetic body such as a permalloy (NiFe), (CoFe), (CoFeNi), (CoNbZr), (FeAlSi), (CoZrO) and a silicon steel or the like. At least one of the first magnetic layer 14a, the second magnetic layer 14b, the magnetic layer 14c and the magnetic layer 14d may include, for example, an alloy including at least one of iron, nickel and cobalt.

The electrode layer 15c, the electrode layer 15d, the electrode layer 16c and the electrode layer 16d are formed in order to improve reliability of wire bonding and connection to a solder. The electrode layer 15c and the electrode layer 15d are, for example, made of a nickel (Ni) layer. The electrode layer 16c and the electrode layer 16d are, for example, made of a gold (Au) layer.

As shown in FIG. 1B, in another printed wiring board 100a according to the embodiment, a conductor layer 51 is further provided as an electrode of the printed wiring board 100a. The conductor layer 51 is, for example, electrically connected to the first conductor layer 13a and the second conductor layer 13b. The conductor layer 51 contacts, for example, the first conductor layer 13a, and contacts the second conductor layer 13b. The first conductor layer 13a has a side surface parallel to a YZ-plane, and the side surface contacts the conductor layer 51. The second conductor layer 13b has a side surface parallel to the YZ-plane, and the side surface contacts the conductor layer 51.

An example of a method for manufacturing the printed wiring board according to the first embodiment will be described.

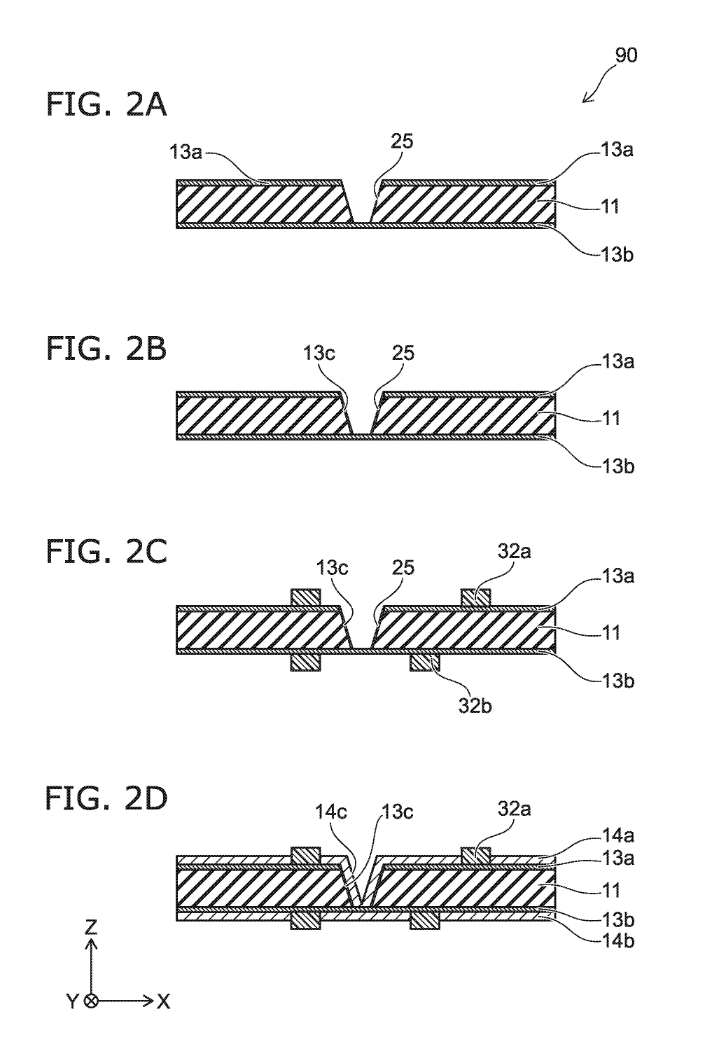

FIG. 2a to FIG. 2D are schematic cross-sectional views illustrating a method for manufacturing the printed wiring board according to the first embodiment.

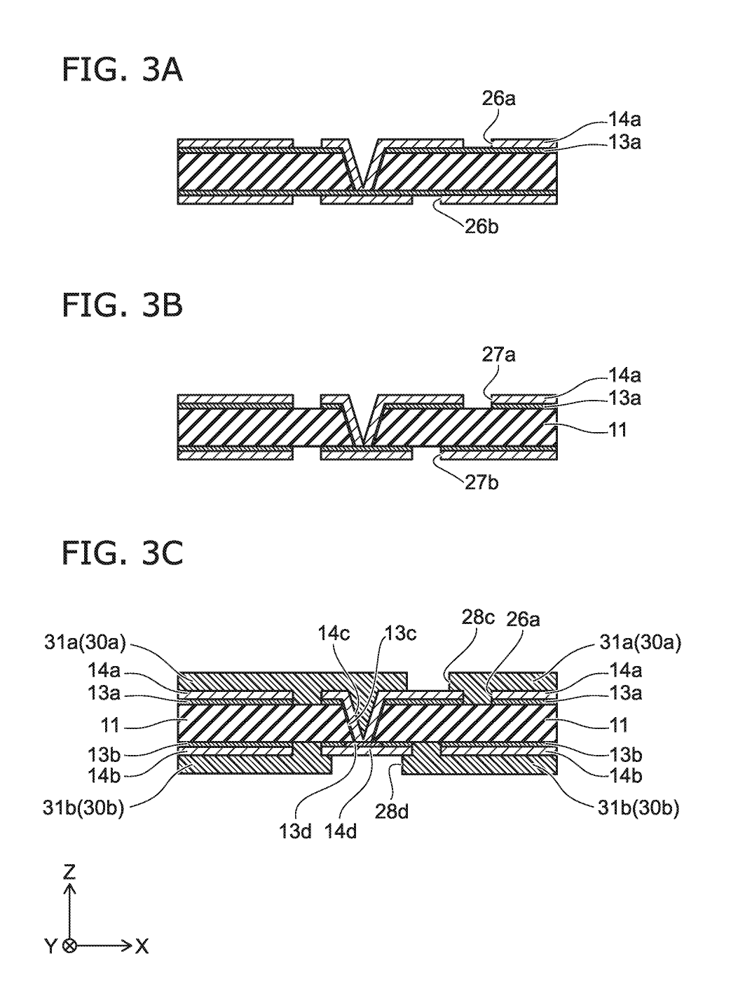

FIG. 3A to FIG. 3C are schematic cross-sectional views illustrating the method for manufacturing the printed wiring board according to the first embodiment.

As shown in FIG. 2A, a printed wiring board 90 is prepared. In the printed wiring board 90, the first conductor layer 13a and the second conductor layer 13b are provided. The insulating layer 11 is provided between the first conductor layer 13a and the second conductor layer 13b.

The via 25 is formed to pierce the first conductor layer 13a and the insulating layer 11 in the Z-direction to reach the second conductor layer 13b. The first conductor layer 13a includes, for example, copper. The second conductor layer 13b includes, for example, copper.

As shown in FIG. 2B, for example, electroless plating of copper is performed on a surface of the via 25. Copper is adhered onto an inner surface of the via 25 and the conductor layer 13c is formed.

As shown in FIG. 2C, a resist film 32a is formed on a partial upper surface of the first conductor layer 13a. A resist film 32b is formed on a partial lower surface of the second conductor layer 13b.

As shown in FIG. 2D, the first magnetic layer 14a is formed on the upper surface of the first conductor layer 13a, for example, by a method such as an electroplating method, an electroless plating method, a sputtering method and a deposition method. The second magnetic layer 14b is also formed on the lower surface of the second conductor layer 13b by the method such as an electroplating method, an electroless plating method, a sputtering method and a deposition method.

As shown in FIG. 3A, the resist film 32a and the resist film 32b are removed. An opening 26a is formed on a portion of the resist film 32a removed. An opening 26b is formed on a portion of the resist film 32b removed.

As shown in FIG. 3B, the first conductor layer 13a and the second conductor layer 13b are selectively removed by etching. An opening 27a is formed to reflect the opening 26a. An opening 27b is formed to reflect the opening 26b.

As shown in FIG. 3C, a resist film 30a is formed on an upper surface of the insulating layer 11, on an upper surface of the first magnetic layer 14a and on an upper surface of the magnetic layer 14c. The resist film 30a is patterned to form a solder resist film 31a. An opening 28c is formed on the upper surface of the magnetic layer 14c. A resist film 30b is formed on a lower surface of the insulating layer 11, on a lower surface of the second magnetic layer 14b and on a lower surface of the magnetic layer 14d. The resist film 30b is patterned to form a resist film 31b. An opening 28d is formed on the upper surface of the magnetic layer 14d.

As shown in FIG. 1A, electroplating of nickel (Ni) is performed on the upper surface of the magnetic layer 14c in the opening 28c. The electrode layer 15c is formed on the upper surface of the magnetic layer 14c in the opening 28c. Electroplating of gold (Au) is performed on an upper surface of the electrode layer 15c. The electrode layer 16c is formed on the upper surface of the electrode layer 15c. Similar to formation of the electrode layer 15c, the electrode layer 15d is formed on a lower surface of the magnetic layer 14c in the opening 27d. Similar to formation of the electrode layer 16c, the electrode layer 16d is formed. Electrodes formed of the electrode layer 15c and the electrode layer 16c are used, for example, as electrodes for wire bonding and soldering.

In this manner, the printed wiring board 100 is formed.

In the first embodiment, one example of forming electrodes for wire bonding on the upper surface of the magnetic layer 14c in the opening 27c is shown. Surface processing on the upper surface of the magnetic layer 14c in the opening 27c may be performed by at least one method of nickel plating, gold plating and solder leveler.

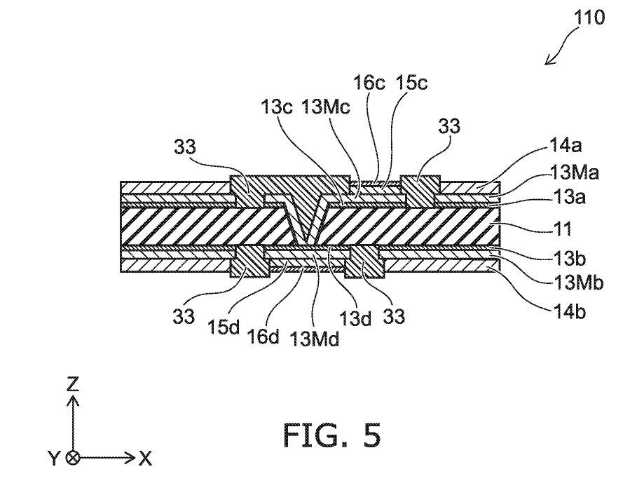

FIG. 5 is a schematic cross-sectional view illustrating another printed wiring board according to the first embodiment.

As shown in FIG. 5, compared a printed wiring board 110 according to the first embodiment with the printed wiring board 100, a third conductor layer 13Ma is further provided between the first conductor layer 13a and the first magnetic layer 14a. A fourth conductor layer 13Mb is further provided between the second conductor layer 13b and the second magnetic layer 14b. At least one of the third conductor layer 13Ma and the fourth conductor layer 13Mb includes at least one of copper, gold, silver and aluminum. A thickness of the third conductor layer 13Ma is thicker than a thickness of the first conductor layer 13a. A thickness of the fourth conductor layer 13Mb is thicker than a thickness of the second conductor layer 13b.

A conductor layer 13Mc is further provided between the conductor layer 13c and the electrode layer 15c. The conductor layer 13Mc is further provided between the conductor layer 13c and a resist film 33. A conductor layer 13Md is further provided between the conductor layer 13d and the electrode layer 15d. At least one of the conductor layer 13Mc and the conductor layer 13Md includes at least one of copper, gold, silver and aluminum.

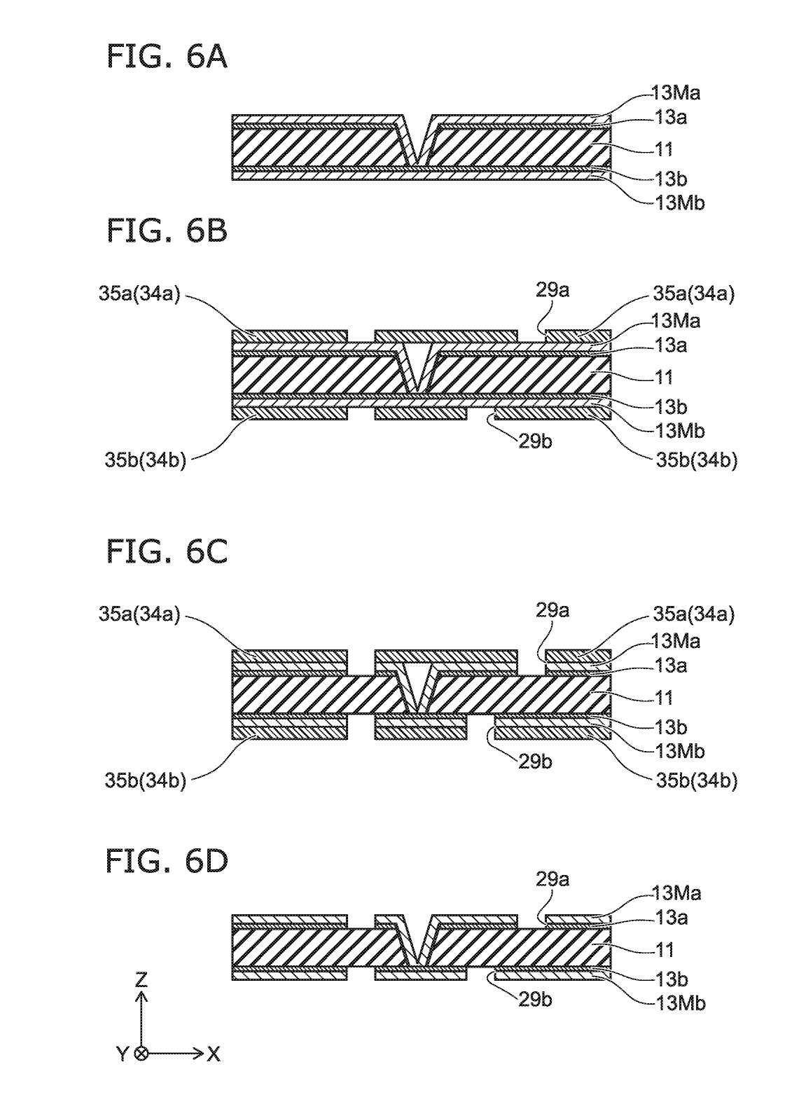

FIG. 6A to FIG. 6D are schematic cross-sectional views illustrating a method for manufacturing another printed wiring board according to the first embodiment.

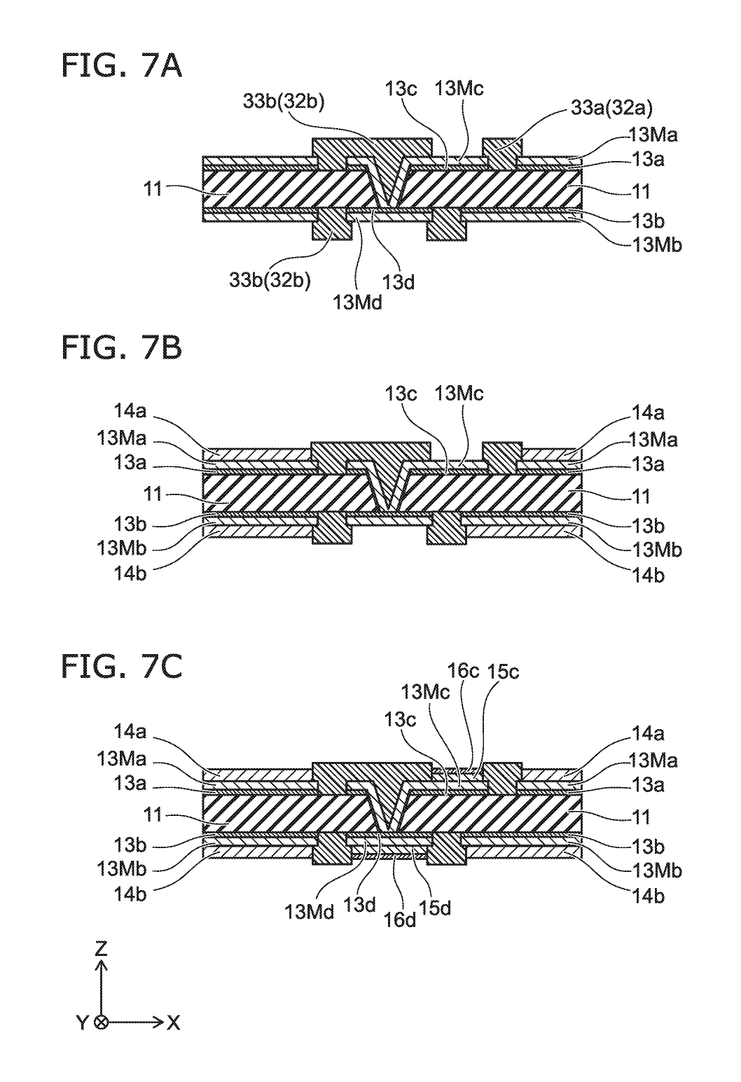

FIG. 7A to FIG. 7C are schematic cross-sectional views illustrating the method for manufacturing another printed wiring board according to the first embodiment.

The method for manufacturing the printed wiring board 110 according to the first embodiment is the same as the method for manufacturing the printed wiring board 100 according to the first embodiment before electroless plating (see FIG. 2B) of copper is performed on the inner surface of the via 25

As shown in FIG. 6A, copper is electroplated on the upper surface of the first conductor layer 13a and the lower surface of the second conductor layer 13b. The third conductor layer 13Ma is formed on the upper surface of the first conductor layer 13a and the fourth conductor layer 13Mb is formed on the lower surface of the second conductor layer 13b.

As shown in FIG. 6B, a resist film 34a is formed on an upper surface of the third conductor layer 13Ma. The resist film 34a is, for example, a dry film. The resist film 34a is patterned. A part of the resist film 34a is removed to form a resist film 35a. An opening 29a is formed on a portion of the resist film 34 partially removed. A resist film 34b is formed on a lower surface of the fourth conductor layer 13Mb. The resist film 34b is, for example, a dry film. The resist film 34b is patterned. A resist film 35b is formed on a portion of the resist film 34b partially removed. An opening 29b is formed on a portion of the resist film 34b partially removed.

As shown in FIG. 6C, etching is performed on the first conductor layer 13a and the third conductor layer 13Ma. The first conductor layer 13a and the third conductor layer 13Ma are selectively removed. Etching is performed on the second conductor layer 13b and the fourth conductor layer 13Mb. The second conductor layer 13a and the fourth conductor layer 13Mb are selectively removed.

As shown in FIG. 6D, the resist film 35a and the resist film 35b are removed.

As shown in FIG. 7A, the resist film 32a is formed on a partial upper surface of the conductor layer 13Mc and on a partial upper surface of the insulating layer 11. The resist film 32a is patterned. A portion of the resist film 32a is removed to form a resist film 33a. The resist film 32b is formed on a partial lower surface of the conductor layer 13Md and on a partial lower surface of the insulating layer 11. The resist film 32b is patterned. A part of the resist film 32b is removed to form a resist film 33b.

As shown in FIG. 7B, a voltage is applied to a plated wire (not shown) electrically connected to the third conductor layer 13Ma, and for example, electroplating of a permalloy is performed. The first magnetic layer 14a is formed on the upper surface of the first conductor layer 13a. A voltage is applied to a plated wire (not shown) electrically connected to the fourth conductor layer 13Mb, and for example, electroplating of a permalloy is performed. The second magnetic layer 14b is formed on a lower surface of the second conductor layer 13b.

As shown in FIG. 7C, a voltage is applied to a plated wire (not shown) electrically connected to the conductor layer 13Mc, and electroplating of nickel is performed. The electrode layer 15c is formed on an upper surface of the conductor layer 13Mc. A voltage is applied to a plated wire (not shown) electrically connected to the conductor layer 13Mc and electroplating of gold is performed. The electrode layer 16c is formed on an upper surface of the electrode layer 15c. A voltage is applied to a plated wire (not shown) electrically connected to the conductor layer 13Md and electroplating of nickel is performed. The electrode layer 15d including nickel is formed on a lower surface of the conductor layer 13Md. A voltage is applied to a plated wire (not shown) electrically connected to the conductor layer 13Md and electroplating of gold is performed. The electrode layer 16d is formed on a lower surface of the electrode layer 15d.

Examples of characteristics of the printed wiring board according to the first embodiment will be described.

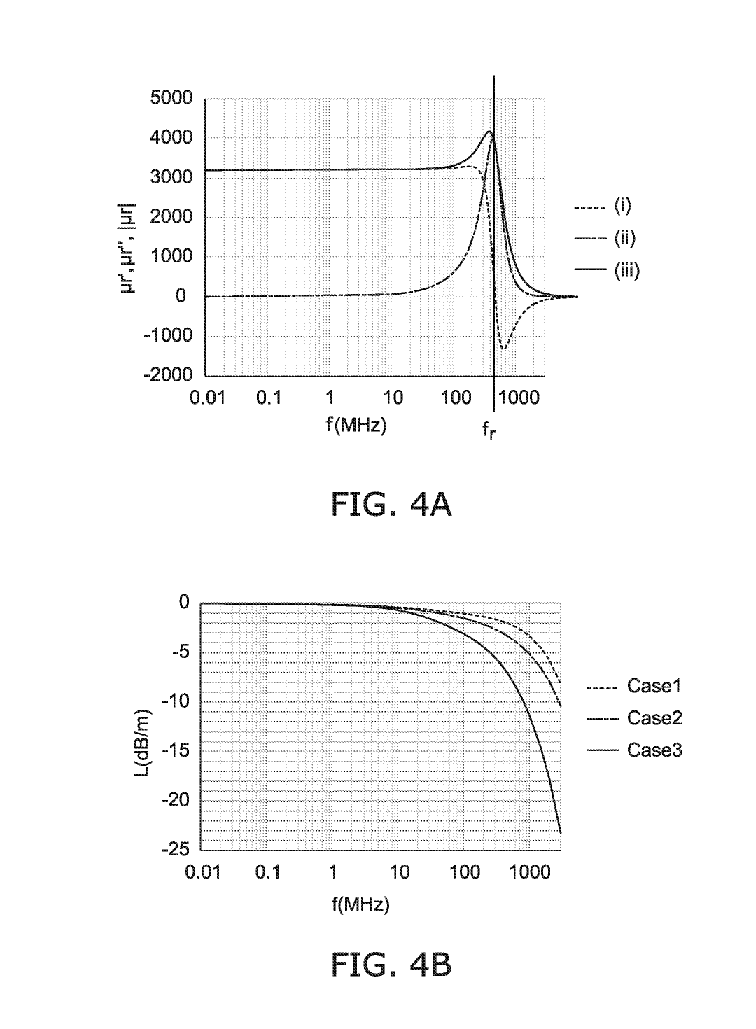

FIG. 4A shows a graph illustrating frequency characteristics of a complex relative permeability of a permalloy.

A horizontal axis of FIG. 4A represents a frequency f. A vertical axis of FIG. 4A represents a complex relative permeability.

A characteristic (i) shown in FIG. 4A shows a real part μᵣ′ of the complex relative permeability of the permalloy.

A characteristic (ii) shown in FIG. 4A shows an imaginary part μᵣ′ of the complex relative permeability of the permalloy.

A characteristic (iii) shown in FIG. 4A shows the absolute value |μᵣ| of the complex relative permeability of the permalloy.

As shown in FIG. 4A, a ferromagnetic resonance frequency fᵣ of the permalloy is about 470 MHz. The real part μᵣ′ of the complex relative permeability of the permalloy is 0 at the frequency f of about 470 MHz. The imaginary part μᵣ′ of the complex relative permeability of the permalloy and the absolute value |μᵣ| of the complex relative permeability are close to the maximum value. The imaginary part μᵣ′ of the complex relative permeability of the permalloy is a loss component. When the imaginary part μᵣ′ of the complex relative permeability of the permalloy is high, the loss is large.

FIG. 4B shows a graph illustrating frequency characteristics of the transmission loss.

FIG. 4B shows examples of simulation results of the relationship of the transmission loss and the frequency. The frequency characteristics of the permalloy shown in FIG. 4A are used for the real part μᵣ′ of the complex relative permeability of the permalloy, the imaginary part μᵣ″ of the complex relative permeability of the permalloy and the absolute value |μᵣ| of the complex relative permeability. A horizontal axis of FIG. 4B represents the frequency f. The vertical axis of FIG. 4B represents the transmission loss L. FIG. 4B shows cases of “Case 1” to “Case 3”.

In “Case 1”, the first magnetic layer 14a and the second magnetic layer 14b are not provided. In “Case 3”, the first magnetic layer 14a is provided on the upper surface of the first conductor layer 13a, and the second magnetic layer 14b is provided on the lower surface of the second conductor layer 13b. “Case 3” corresponds to one example of the first embodiment based on the printed wiring board 100 shown in FIG. 1. In “Case 2”, the first magnetic layer 14a is provided on the upper surface of the third conductor layer 13Ma, and the second magnetic layer 14b is provided on the lower surface of the fourth conductor layer 13Mb. “Case 2” corresponds to one example of the first embodiment based on the printed wiring board 110 shown in FIG. 5.

In the following, conditions of simulations are shown.

The insulating layer 11 is glass epoxy. A relative permittivity of the insulating layer 11 is 4.4. A thickness of the insulating layer 11 is 0.20 mm (millimeter). Thicknesses t₁ of the first conductor layer 13a and the second conductor layer 13b are 35 μm (micrometer), respectively. Thicknesses t₂ of the first magnetic layer 14a and the second magnetic layer 14b are 35 μm (micrometer), respectively. Materials of the first conductor layer 13a and the second conductor layer 13b are copper. Materials of the first magnetic layer 14a and the second magnetic layer 14b are a permalloy.

As shown in FIG. 4B, when the frequency f is not more than 1 MHz, the transmission losses L in “Case 1” to “Case 3” are not more than 0.20 dB/m. When the frequency f is not more than 1 MHz, the transmission losses L in “Case 1” to “Case 3” are almost the same.

When the frequency f is not less than 100 MHz (megahertz), the transmission loss L in “Case 2” is larger than the transmission loss L in “Case 1” and the transmission loss L in “Case 2”. For example, when the frequency f is 100 MHz, the transmission loss L in “Case 1” is −1.1 dB/m (decibel per meter). The transmission loss L in “Case 2” is −1.5 dB/m. The transmission loss L in “Case 3” is −3.1 dB/m.

A thickness d of skin of a current flowing through a transmission line is represented by the following formula 1.

$$d = \sqrt{\frac{ρ}{π \times f \times {μ}_{0} \times \vert {μ}_{r} \vert}}$$

ρ is electric resistivity. f is frequency of current. μ₀ is permeability of vacuum. |μᵣ| is the absolute value of complex relative permeability.

For example, the electric resistivity of copper is 1.7×10⁻⁸ Ω·m (ohm meter), the absolute value |μᵣ| of the complex relative permeability of copper is 1, and the skin depth of the first conductor layer 13a at the frequency of 100 MHz is about 6.6 μm.

For example, the electric resistivity of the permalloy is 3.0×10⁻⁷ Ω·m, the absolute value |μᵣ| of the complex relative permeability of the permalloy is 3200, the skin depth of the first magnetic layer 14a at the frequency of 100 MHz is about 1.5 μm.

The skin depth of the first conductor layer 13a and the second conductor layer 13b at the frequency of 100 MHz is thinner than the thickness t₁ of the first conductor layer 13a and the second conductor layer 13b. The skin depth of the first magnetic layer 14a and the second magnetic layer 14b at the frequency of 100 MHz is thinner than the thickness t₂ of the first magnetic layer 14a and the second magnetic layer 14b. In the first conductor layer 13a and the first magnetic layer 14a, the current is biased near the skin due to a skin effect. Resistances of the first conductor layer 13a and the first magnetic layer 14b increase and the loss is increased. When the frequency f is not less than 100 MHz, the current is further biased near the skin due to increase of frequency.

The transmission line in “Case 3” is provided with the magnetic layer 14c and the magnetic layer 14d in comparison with the transmission lines in “Case 1” and “Case 2”. The influence by the skin effect due to the magnetic layer 14c and the magnetic layer 14d being provided is large. Therefore, the transmission loss L in “Case 3” is larger than the transmission loss L in “Case 1” and “Case 2”.

A switching power supply controls switching by a pulse signal of a few kHz (kilohertz). Ripple occurs in the pulse signal. Noise of number 100 MHz to number GHz occurs due to occurrence of the ripple, and transmits through the transmission line as a noise. This is referred to as a conduction noise.

The first magnetic layer 14a, the second magnetic layer 14b, the magnetic layer 14c and the magnetic layer 14d of the printed wiring board 100 according to the first embodiment include a permalloy, for example. Thereby, the transmission loss with a frequency f of 100 MHz or more is large. The conduction noise transmitting through the transmission line and having the frequency f of 100 MHz or more can be small. As a result, a printed wiring board capable of suppressing a high frequency noise can be provided.

The conduction noise can be suppressed by further providing another magnetic layer on the first magnetic layer 14a of the printed wiring board 100. Another magnetic layer includes, for example, a permalloy.

A radiation noise is referred to as a noise that the conduction noise transmitting through the transmission line such as a power supply line forms a radiation source to be radiated. The frequency of the radiation noise is, for example, approximately 100 MHZ to number of GHz. Therefore, the radiation noise can also be suppressed by suppressing the conduction noise.

### Second Embodiment

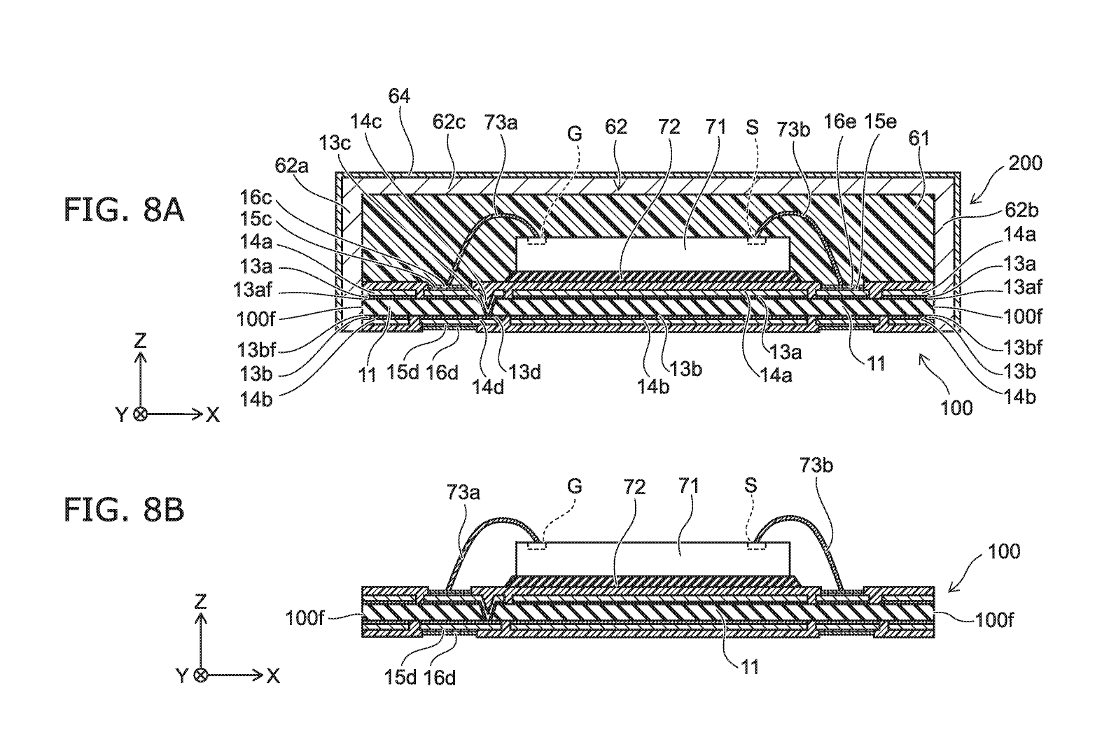

FIG. 8A and FIG. 8B are schematic cross-sectional views illustrating a magnetic shield package according to a second embodiment.

As show in FIG. 8A, a magnetic shield package 200 includes the printed wiring board according to the first embodiment (for example, the printed wiring board 100), and a first shield section 62. The first shield section 62 includes a first potion 62a, a second portion 62b, and a third portion 62c. The first portion 62a is along the ZY-plane or the ZX-plane. The second portion 62b is also along the YZ-plane or the ZX-plane. The third portion 62c is along the XY-plane. A part of the third portion 62c is linked to a part of the first portion 62a. Another part of the third portion 62c is linked to a part of the second portion 62b.

The first portion 62a and the first magnetic layer 14a are connected in the X-direction. The first portion 62a and the second magnetic layer 14b are connected on a side surface of the printed wiring board 100. The first portion 62a and the first conductor layer 13a are connected in the X-direction. The first portion 62a and the second conductor layer 13b are connected on the side surface of the printed wiring board 100. The second portion 62b and the first magnetic layer 14a are connected in the X-direction. The second portion 62b and the second magnetic layer 14b are connected on the side surface of the printed wiring board 100. The second portion 62b and the first conductor layer 13a are connected in the X-direction. The second portion 62b and the second conductor layer 13b are connected on the side surface of the printed wiring board 100. The third portion 62c and the first magnetic layer 14a are connected to in the Z-direction.

A protection section 64 may be provided on a surface of the first shield section 62. The protection section 64 prevents erosion of the first shield section 62. The protection section 64 includes at least one of an insulator, a conductor Q of a non-magnetic body and a conductor M of a soft magnetic body. The conductor Q of the non-magnetic body includes, for example, a stainless steel (SUS) and titanium (Ti). The conductor M of the soft magnetic body includes, for example, nickel.

A sealing resin 61 is provided between the first shield section 62 and the printed wiring board 100. A magnetic shield package 200 is, for example, a package of a LGA (land Grid Array) type.

A magnetic device 71 is provided, for example, on the printed wiring board 100 via a mount member 72. A signal terminal S of the magnetic device 71 and an electrode layer 16e are connected by a wire 73b. A ground terminal G of the magnetic device 71 and the electrode layer 16c are connected by a wire 73a. The sealing resin 61 is provided on the magnetic device 71 and seals the magnetic device 71. The first shield section 62 is provided on the sealing resin 61 and covers the magnetic device 71 and the sealing resin 61.

The magnetic device 71 is, for example, a current sensor measuring a magnetic field strength. The magnetic device 71 is, for example, an AMR element (An-Isotropic Magnetoresistive device), a GMR element (Giant Magneto Resistive device), a TMR element (Tunnel Magneto Resistance device). The magnetic device 72 may be, for example, an MRAM (Magnetoresistive Random Access Memory).

The wire 73a and the wire 73b include, for example, gold (Au). The sealing resin 61 includes, for example, an epoxy resin. The first shield section 62 includes a conductor of a soft magnetic body. A relative permeability of the first shield section 62 is, for example, not less than 1000.

The first shield section 62 includes, for example, one of iron, nickel and cobalt. The first shield section 62 includes, for example, at least one of a permalloy (NiFe), (CoFe), (CoFeNi), (CoNbZr), (FeAlSi), (CoZrO) and a silicon steel or the like.

In the second embodiment, the example where the first portion 62a and the second conductor layer 13b overlap in the X-direction is shown. In the second embodiment, the example where the second portion 62b and the second conductor layer 13b are connected on the side surface of the printed wiring board 100 is shown. A part of the second conductor layer 13b and the first portion 62a may be connected on the side surface of the printed wiring board 100. A part of the second conductor layer 13b and the second portion 62b may be connected on the side surface of the printed wiring board 100. The printed wiring board 110 may be used.

The first shield section 62 may include a plurality of layers. Each layer of the plurality of layers includes a conductor of the soft magnetic body. The first shield section 62 may include soft magnetic bodies of two types or more.

One example of a method for manufacturing the magnetic shield package according to the second embodiment is described.

As shown in FIG. 8B, the printed wiring board 100 is prepared. The mount member 72 is applied on an upper surface of the printed wiring board 100. The magnetic device 71 is mounted on an upper surface of the mount member 72. The ground terminal G and the electrode layer 16c are connected by the wire 73a. The signal terminal S and the electrode layer 16e are connected by the wire 73b.

As shown in FIG. 8A, the sealing resin 61 is formed to seal the upper surface of the printed wiring board 100 and the magnetic device 71. The first shield section 62 is formed on a surface of the sealing resin 61 and on the side surface 100f of the printed wiring board 100 by at least one method, for example, of an electroplating method, an electroless plating method, a sputtering method and a deposition method.

A thin conductor of a non-magnetic body or a layer of a conductor of a soft magnetic body is formed on the surface of the sealing resin 61 or on the side surface 100f by at least one method, for example, of an electroplating method, an electroless plating method, a sputtering method and a deposition method. After that, a relatively thick layer of a conductor of a soft magnetic body is formed by the electroplating method. The first shield section 62 may be formed in this way.

The protection section 64 is formed of, for example, an insulating material on an upper surface of the first shield section 62. The protection section 64 may be formed of, for example, the conductor Q of the non-magnetic body including one of a stainless steel (SUS) and titanium (Ti) on the surface of the first shield section 62. The protection section 64 may be formed of, for example, the conductor M of the soft magnetic body including nickel on the upper surface of the first shield section 62.

Characteristics of the magnetic shield package according to the second embodiment are described.

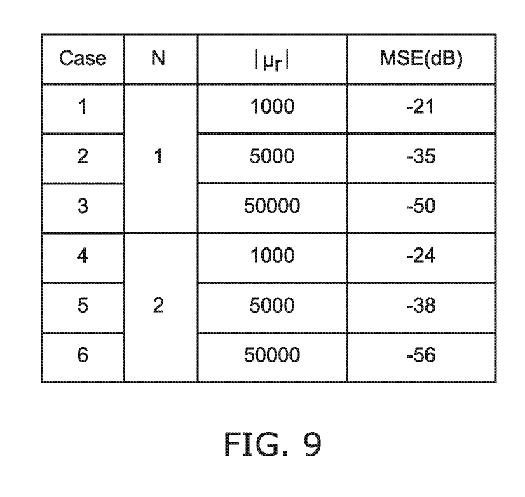

FIG. 9 shows a graph illustrating characteristics of the magnetic shield package.

FIG. 9 shows one example of the simulation results of the shield characteristics of the magnetic shield package. In the magnetic shield package 200, the magnetic field strength near the magnetic device 71 in the case of not providing the first shield section 62 is taken as the reference, and a rate of attenuation of the magnetic field strength near the magnetic device 71 in the case of not providing the first shield section 62 is defined as a magnetic shielding effectiveness (MSE), and analysis is performed. Units of the magnetic shielding effectiveness (MSE) are decibel.

FIG. 9 shows cases of “Case 1” to “Case 6”. Number of layers of the first magnetic layer 14a to magnetic layer 14d is set to be number of layers N. The absolute value of the complex relative permeability of the first magnetic layer 14a to the magnetic layer 14d is set to be |μᵣ|. The magnetic shielding effectiveness is set to be MSE. In “Case 1”, the number of layers N is one layer, and |μᵣ| is 5000. In “Case 2”, the number of layers N is 1 layer, and |μᵣ| is 5000. In “Case 3”, the number of layers N is 1 layer, and |μᵣ| is 5000. In “Case 4”, the number of layers N is 2 layers, and |μᵣ| is 1000. In “Case 5”, the number of layers N is 2 layers, and |μᵣ| is 5000. In “Case 6”, the number of layers N is 2 layers, and |μᵣ| is 5000.

As shown in FIG. 9, in “Case 1”, the magnetic shielding effectiveness MSE is −21 dB. In “Case 2”, the magnetic shielding effectiveness MSE is −35 dB. In “Case 3”, the magnetic shielding effectiveness MSE is −50 dB. In “Case 4”, the magnetic shielding effectiveness MSE is −24 dB. In “Case 5”, the magnetic shielding effectiveness MSE is −38 dB. In “Case 6”, the magnetic shielding effectiveness MSE is −56 dB.

In the magnetic shield package 200, the magnetic shielding effectiveness MSE can be higher by providing the first shield section 62. When the magnetic device 71 is surrounded by the magnetic shield package with a high magnetic shielding effectiveness MSE, even if a high magnetic field noise is applied to the package from the outside, the magnetic device 71 is not influenced by the magnetic field noise and can be operated normally.

The first shield section 62 and the first magnetic layer 14a are electrically connected. The first shield section 62 and the second magnetic layer 14b are electrically connected. The first shield section 62, the first magnetic layer 14a and the second magnetic layer 14b are provided around the magnetic device 71. The first shield section 62, the first magnetic layer 14a and the second magnetic layer 14b include a conductor of a soft magnetic body. Therefore, the conductor of the soft magnetic body is provided around the magnetic device 71.

This suppresses the conduction noise and the radiation noise generated from at least one of the magnetic device 71, the wire 73a, the wire 73b, the electrode layer 16a and the electrode layer 16b from leaking to the outside of the magnetic shield package 200.

Therefore, the second embodiment can also further suppress the radiation noise. The second embodiment can also suppress electromagnetic wave and static electricity entering from the outside into the inside of the magnetic shield package 200.

The magnetic shield package 200 according to the second embodiment has been described as one example of the package of an LGA type. The magnetic shield package 200 may be, for example, a BGA (Ball Grid Array) type. The magnetic shield package 200 may be, for example, a QFN (Quad Flat Non lead package) type.

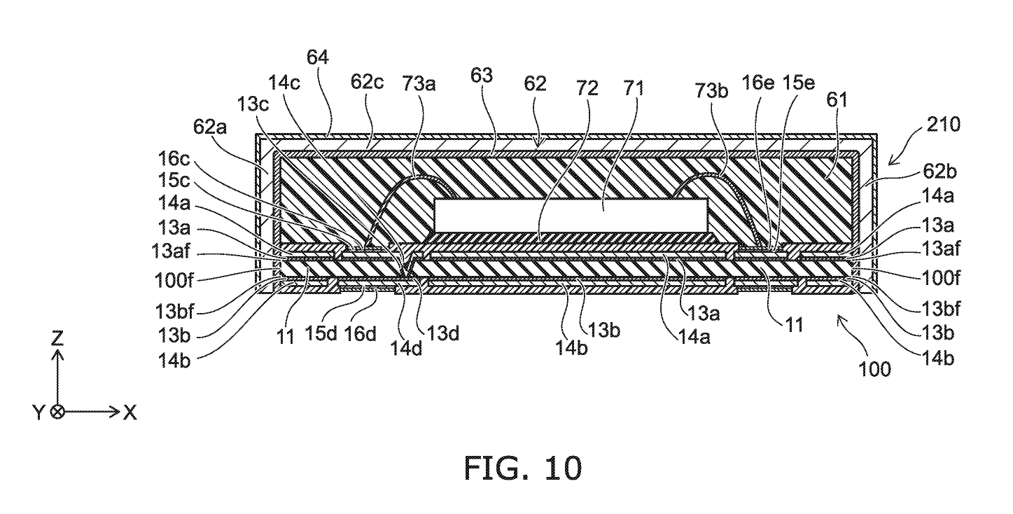

FIG. 10 is a schematic cross-sectional view illustrating another magnetic shield package according to the second embodiment.

As shown in FIG. 10, a magnetic shield package 210 is further provided with a second shield section 63 in comparison with the magnetic shield package 200. The second shield section 63 is provided between the first shield section 62 and the first magnetic layer 14a. The second shield section 63 and the first magnetic layer 14a overlap in the X-direction. The second shield section 63 and the first magnetic layer 14a overlap in the Z-direction.

The seconds shield section 63 includes a conductor of a non-magnetic body. The second shield section 63 includes, for example, copper, nickel and a stainless steel (SUS).

### Third Embodiment

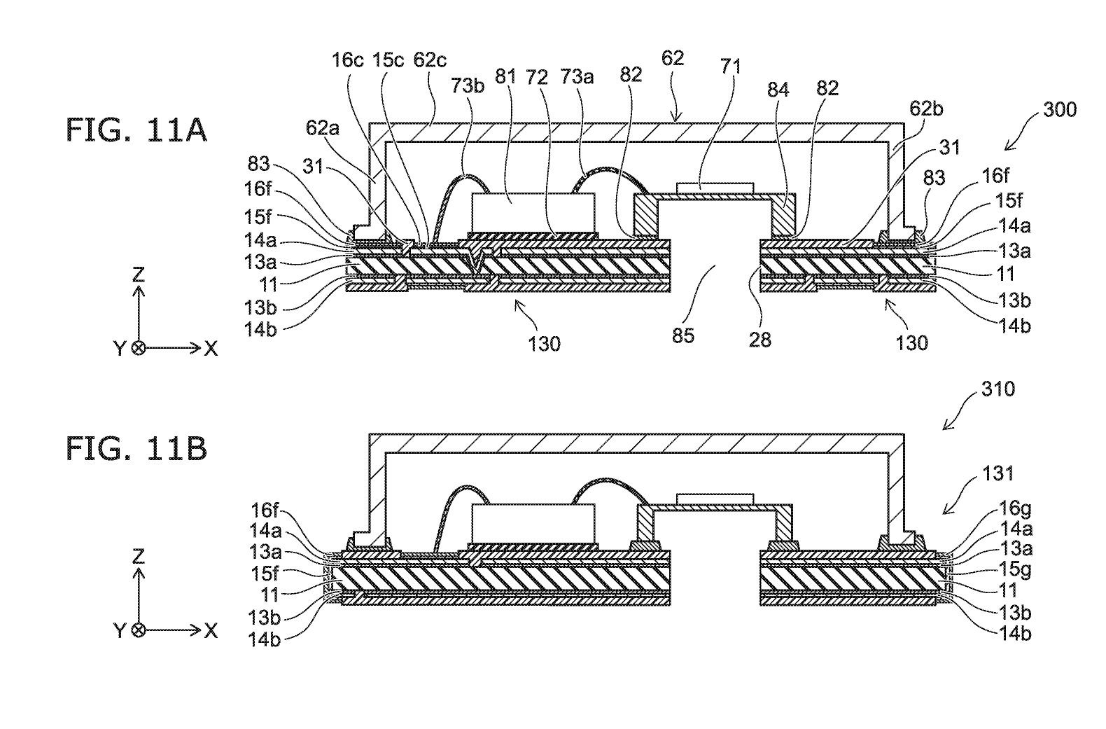

FIG. 11A and FIG. 11B are schematic cross-sectional views illustrating a magnetic shield package according to a third embodiment.

As shown in FIG. 11A, a magnetic shield package 300 according to the third embodiment is further provided with a printed wiring board 130.

A diaphragm 84 is fixed to the printed wiring board 130 by an adhesive agent 82. The adhesive agent 82 includes, for example, a material such as silicone, a solder and a conductive paste. The magnetic device 71 is mounted on the diaphragm 84. A signal processing device 81 is also mounted on the printed wiring board 130.

A second electrode layer 16f is provided between the first shield section 62 and the first magnetic layer 14a. A first electrode layer 15f is provided between the second electrode layer 16f and the first magnetic layer 14a. The first portion 62a and the first magnetic layer 14a overlap in the Z-direction. The first shield section 62 is adhered to the second electrode layer 16f via an adhesive agent 83, and fixed to the printed wiring board 130.

The signal processing device 81 and the second electrode layer 16c are connected by the wire 73b. The signal processing device 81 and the diaphragm 84 are connected by the wire 73a.

The magnetic shield package 300 is used, for example, as a package for an acoustic sensor. The printed wiring board 130 is provided with a through hole 85. The diaphragm 84 is provided on the through hole 85. Acoustic wave passes through the through hole 85 to arrives at the diaphragm 84. When the acoustic wave arrives at the diaphragm, the diaphragm 84 is deflected. The amount of deflection of the diaphragm 84 is sensed by the magnetic device 71. The magnetic device 71 is provided on the diaphragm 84 and senses an amount of deflection of the diaphragm 84. The first shield section 62 is provided on the magnetic device 71 and covers the diaphragm 84 and the magnetic device 71.

The first shield section 62, the first magnetic layer 14a and the second magnetic layer 14b are provided around the magnetic device 71, the diaphragm 84 and the signal processing device 81. The first shield section 62, the first magnetic layer 14a and the second magnetic layer 14b are made of the conductor of the soft magnetic body. Therefore, the magnetic device 71 and the signal processing device 81 are surrounded by the conductor of the soft magnetic body.

Thereby, the magnetic device 71 is surrounded by the magnetic shield package with a high magnetic shielding effectiveness MSE, and thus even if a high magnetic field noise is applied to the package from the outside, the magnetic device 71 is not influenced by the magnetic field noise and can be operated normally.

The adhesive agent 82 is made of, for example, silicone, a solder and a conductive adhesive agent. The adhesive agent 83 is made of silicone, a solder, a conductive adhesive agent, or an adhesive agent including a magnetic particle made of an alloy including at least one of nickel, iron and cobalt (Co). In the case where the adhesive agent 83 includes the magnetic particle, a magnetic resistance between the first shield section 62 and the first magnetic layer 14a decreases and the magnetic shielding effectiveness can be increased.

As shown in FIG. 11B, in another magnetic shield package 310 according to the embodiment, the first electrode layer 15f and the second electrode layer 16f are further provided on a plane parallel to the YZ-plane of the first magnetic layer 14a. The first electrode layer 15f and the first magnetic layer 14a are connected in the X-direction. The first electrode layer 15f and the second magnetic layer 14b are connected in the X-direction. The first electrode layer 15f and the first conductor layer 13a are connected in the X-direction. The first electrode layer 15f and the second conductor layer 13b are connected in the X-direction.

According to the plurality of embodiments described above, a printed wiring board and a magnetic shield package capable of suppressing a high frequency noise can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. The embodiments described above can be practiced in combination with each other.

What is claimed is:

1. A printed wiring board comprising:
a first magnetic layer;
a second magnetic layer;
an insulating layer provided between the first magnetic layer and the second magnetic layer;
a first conductor layer provided between the insulating layer and the first magnetic layer; and
a second conductor layer provided between the insulating layer and the second magnetic layer.

2. The board according to claim 1, wherein the first magnetic layer is not connected to the first conductor layer in a second direction intersecting a first direction from the second magnetic layer toward the first magnetic layer, and the second magnetic layer is not connected to the second conductor layer in the second direction.

3. The board according to claim 1, wherein at least one of a coercive force of the first magnetic layer and a coercive force of the second magnetic layer is less than 5000 A/m.

4. The board according to claim 1, wherein
at least one of a relative permeability of the first conductor layer and a relative permeability of the second conductor layer is not less than 1.0 and not more than 2.0, and
at least one of a resistivity of the first conductor layer and a resistivity of the second conductor layer is not less than 1.5×1⁻⁸ Ω·m and not less than 1.0×1⁻⁶ Ω·m.

5. The board according to claim 1, wherein at least one of the first conductor layer and the second conductor layer includes at least one of copper, gold, silver and aluminum.

6. The board according to claim 1, wherein at least one of a resistivity of the first magnetic layer and a resistivity of the second magnetic layer is not less than 2×10⁻⁸ Ω·m and not more than 1.0×1⁻⁴ Ω·m.

7. The board according to claim 1, wherein at least one of the first magnetic layer and the second magnetic layer is made of an elemental substance of iron, nickel and cobalt, or an alloy including at least one of iron, nickel and cobalt.

8. The board according to claim 1, further comprising:
a third conductor layer provided between the first magnetic layer and the first conductor layer; and
a fourth conductor layer provided between the second magnetic layer and the second conductor layer.

9. The board according to claim 8, wherein at least one of the third conductor layer and the fourth conductor layer includes at least one of copper, gold, silver and aluminum.

10. The board according to claim 8, wherein
a thickness of the third conductor layer is thicker than a thickness of the first conductor layer, and
a thickness of the fourth conductor layer is thicker than a thickness of the second conductor layer.

11. The board according to claim 1, further comprising a first wiring layer and a second wiring layer,
the insulating layer having a first surface and a second surface opposite the first surface,
the first magnetic layer and the first conductor layer being provided on the first surface,
the second magnetic layer and the second conductor layer being provided on the second surface,
the first wiring layer being provided on the first surface and being apart from the first magnetic layer and the first conductor layer, and
the second wiring layer being provided on the second surface and being apart from the second magnetic layer and the second conductor layer.

12. The board according to claim 11, further comprising a third magnetic layer and a fourth magnetic layer,
the first wiring layer being provided between the third magnetic layer and the insulating layer, and
the second wiring layer being provided between the fourth magnetic layer and the insulating layer.

13. A magnetic shield package comprising:
a printed wiring board: and
a first shield section,
the printed wiring board including:
a first magnetic layer;
a second magnetic layer;
an insulating layer provided between the first magnetic layer and the second magnetic layer;
a first conductor layer provided between the insulating layer and the first magnetic layer; and
a second conductor layer provided between the insulating layer and the second magnetic layer,
the first shield section including:
a first portion along a first direction from the second magnetic layer toward the first magnetic layer;
a second portion arranged with the first portion in a second direction and along the first direction, the second direction intersecting the first direction; and
a third portion along the second direction,
the first magnetic layer, the second magnetic layer, the first conductor layer and the second conductor layer being provided between the first portion and the second portion, and
the third portion overlapping the first magnetic layer in the first direction.

14. The package according to claim 13, wherein a relative permeability of the first shield section is not less than 1000.

15. The package according to claim 13, wherein the first shield section includes at least one of iron, nickel and cobalt.

16. The package according to claim 13, wherein the first conductor layer is electrically connected to a ground terminal of a magnetic device provided between the first magnetic layer and the first shield section.

17. The package according to claim 13, further comprising:
a second shield section provided between the first shield section and the first magnetic layer,
the second shield section and the first magnetic layer being connected in the second direction, and
the second shield section and the first magnetic layer being connected in the first direction.

18. The package according to claim 13, wherein the second shield section includes at least one of copper, silver, gold nickel, titanium and a stainless steel.

19. The package according to claim 13, further comprising:
a magnetic device provided on the printed wiring board; and
a sealing resin provided on the magnetic device and sealing the magnetic device,
the first shield section being provided on the sealing resin and covering the magnetic device and the sealing resin.

20. The package according to claim 13, further comprising a diaphragm and a magnetic device,
the printed wiring board having a through hole,
the diaphragm being provided on the through hole,
the magnetic device being provided on the diaphragm and sensing an amount of deflection of the diaphragm, and
the first shield section being provided on the magnetic device and covering the diaphragm and the magnetic device.
